(19) United States
(12) Patent Application Publication
(10) Pub. No.: US 2010/0289074 A1
(43) Pub. Date: Nov. 18, 2010

(54) SEMICONDUCTOR DEVICE AND METHOD OF FABRICATING THE SAME

(75) Inventor: Kou-Way Tu, Taipei County (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(73) Assignee: NIKO SEMICONDUCTOR CO., LTD., Taipei (TW)

(21) Appl. No.: 12/506,264

(22) Filed: Jul. 21, 2009

(30) Foreign Application Priority Data
May 15, 2009 (TW) 98116159

(51) Int. Cl. H01L 29/78; H01L 21/336

(52) U.S. Cl. 257/330; 438/270; 257/E29.262; 257/E21.41

(57) ABSTRACT

A semiconductor device is provided. The semiconductor device includes a semiconductor substrate, at least a doped region, an electrical contact layer and a metal oxide semiconductor cell. The semiconductor substrate includes opposing first and second surfaces and at least a trench extending from the second surface into interior portion thereof. The doped region is located in the semiconductor substrate under the bottom of the trench. The dopant concentration of the doped region is higher than that of the semiconductor substrate. The electrical contact layer is located on the second surface of the semiconductor substrate and connects to the doped region. The metal oxide semiconductor cell is located on the semiconductor substrate adjacent the first surface thereof.

### CROSS-REFERENCE TO RELATED APPLICATION

This application claims the priority benefit of Taiwan application serial no. 98116159, filed May 15, 2009. The entirety of the above-mentioned patent application is hereby incorporated by reference herein and made a part of specification.

### BACKGROUND

1. Field of the Invention

The present invention relates to a semiconductor device and a method of fabricating the same, and more particularly to a field effect transistor device, a super junction field effect transistor device, an insulated gate bipolar transistor (IGBT) device, a combination thereof, and a method of fabricating the same.

2. Description of Related Art

A semiconductor device is widely adopted in current electronic products. With the demand of being light, compact, and highly functional and the development in semiconductor manufacturing technologies, a metal oxide semiconductor field effect transistor (MOSFET) and an IGBT combining the features of MOSFET and bipolar junction transistor (BJT) have become main streams in power devices.

For the power devices, because the problem of heat generation is unavoidable, the enhancement in thermal managing ability should be considered seriously. In addition, the quality of the insulating layer surrounding the gate of the transistor, which determines the characteristics and reliability of the power devices, is also an important issue for the power devices. Among the power devices, the AVALANCHE FET, which is developed for preventing avalanche damage, and the COOLMOS, which is developed in 1998 to overcome silicon limitation and successfully reduce the on-resistance, have enhanced the standard of power devices to a high level. The AVALANCHE FET and the COOL MOS are considered as two major supports of making MOS power devices the main stream in the development of power devices.

A typical power MOSFET device usually adopts a vertical structure design, which utilizes a back surface of the semiconductor substrate as a drain electrode and manufactures sources and gates of a plurality of transistors on a front surface of the semiconductor substrate to enhance device density. Since the drains of the transistors are connected in parallel, withstanding current of the power device are relatively high. In order to enhance a breakdown voltage of the power device for meeting market demand, a typical method is to adjust the epitaxial layer on the semiconductor substrate, which has a dopant concentration lower than that of the semiconductor substrate. The thicker the epitaxial layer is, the higher the breakdown voltage of the device can be achieved. However, as the epitaxial layer gets thicker, it takes a longer time to grow the epitaxial layer and the cost gets higher. Moreover, since thermal expansion coefficients of the semiconductor substrate and the epitaxial layer are different, there may be the problem of bending deformation happened on the power device during the high-temperature time-wasting epitaxial process. In addition, the semiconductor substrate is usually the largest resistance component on the current path of the aforementioned semiconductor device. How to reduce the resistance on the current path is also an urgent problem to be solved.

### SUMMARY

A semiconductor device including a semiconductor substrate of a first conductive type, two separated first doped regions of the first conductive type, a first electrical contact layer, and at least a metal oxide semiconductor cell. The semiconductor substrate has a first surface and an opposite second surface and at least two first trenches extending from the second surface of the semiconductor substrate into interior portion thereof. The two first doped regions are respectively located in the semiconductor substrate under bottoms of the two first trenches. A dopant concentration of the first doped region is higher than that of the semiconductor substrate. The first electrical contact layer covers the first doped region. The metal oxide semiconductor cell is located on the first surface of the semiconductor substrate.

According to an embodiment of the present invention, the aforementioned semiconductor device further includes at least a second doped region of the first conductive type located on the second surface. A dopant concentration of the second doped region is higher than that of the semiconductor substrate.

According to an embodiment of the present invention, the semiconductor device further includes two first doped columns of a second conductive type. The two first doped columns, which are located in the semiconductor substrate respectively and separated by a distance, connect to the first doped regions respectively and extend to the metal oxide semiconductor cell. According to an embodiment of the present invention, the first doped columns are formed by an epitaxial material.

According to an embodiment of the present invention, in the semiconductor device, the metal oxide semiconductor cell includes a gate located on the first surface of the semiconductor substrate. Additionally, one of the first doped columns is aligned to the gate. Furthermore, according to another embodiment of the present invention, in the semiconductor device, the metal oxide semiconductor cell includes the gate and two wells of the second conductive type. The gate is disposed on the first surface of the semiconductor substrate. The two wells of the second conductive type are located in the semiconductor substrate at both sides of the gate. The first doped columns are aligned to the wells.

According to an embodiment of the present invention, in the semiconductor device, the semiconductor substrate under the bottom of each first trench includes a cave to separate each first doped region into two portions. In addition, the semiconductor device further includes two second doped regions of the second conductive type. The two second doped regions are respectively located in a bottom of each cave and separated from the metal oxide semiconductor cell. Further, according to another embodiment of the present invention, the semiconductor device further includes a third doped region of the first conductive type and two second doped columns of the second conductive type. A dopant concentration of the third doped region is higher than that of the semiconductor substrate. The third doped region is located on the second surface of the semiconductor substrate. The two second doped columns are located in the semiconductor substrate. The second doped columns are connected to the third doped region and aligned to the metal oxide semiconductor cell. According to an embodiment of the present invention, the second doped columns are formed by an epitaxial material.

A method of fabricating a semiconductor device is further provided in the present invention. In this method, a semiconductor substrate of a first conductive type is provided. This semiconductor substrate includes a first surface and an opposing surface. Next, two separated first trenches are formed in the semiconductor substrate. Each first trench extends from the opposing surface into interior portion of the semiconductor substrate. A first doped region of the first conductive type is formed in the semiconductor substrate under a bottom of each first trench by using an ion implantation process. A dopant concentration of each first doped region is higher than that of the semiconductor substrate. At least a metal oxide semiconductor cell is formed on the first surface of the semiconductor substrate. The semiconductor substrate is thinned by removing a thickness of the semiconductor substrate from the opposing surface to form a second surface. A first electrical contact layer is formed to cover the second surface of the semiconductor substrate and the first doped regions.

According to an embodiment of the present invention, in the method of fabricating the semiconductor device, the first doped regions are formed on the bottoms of the first trenches after the step of forming the metal oxide semiconductor cell and the step of thinning the semiconductor substrate. Alternately, the first doped regions are formed in the semiconductor substrate under the bottoms of the first trenches before the step of forming the metal oxide semiconductor cell and the step of thinning the semiconductor substrate.

According to an embodiment of the present invention, in the method of fabricating the semiconductor device, a filling material is further deposited in each first trench after the first trenches are formed and before the thinning step is performed. Thereafter, the filling material is removed before the first doped regions are formed.

According to an embodiment of the present invention, in the method of fabricating the semiconductor device, in the step of forming the first doped regions, two second doped regions of the first conductive type are also formed on the opposite surfaces of the semiconductor substrate at the both sides of each first trench simultaneously. A pitch of the metal oxide semiconductor cells is no greater than a distance between two adjacent first trenches.

According to an embodiment of the present invention, the method of fabricating the semiconductor device further includes forming two first doped columns of the second conductive type before the first trenches are formed. The first doped columns extend from the opposite surfaces of the semiconductor substrate toward the first surface. Moreover, the first trenches align to first doped columns respectively. Furthermore, a width of the first trench is greater than that of the respective first doped column. A depth of the first trench is smaller than that of the respective first doped column. The first doped regions are adjacent to the respective first doped column. Also, according to an embodiment of the present invention, in the step of forming the first doped columns, two second trenches are formed in the semiconductor substrate. Next, the second trenches are filled with an epitaxial material of the second conductive type.

According to an embodiment of the present invention, in the method of fabricating the semiconductor device, after the first doped regions are formed and before the first electrical contact layer is formed, a cave is formed on the bottom of the first trench so as to separate each first doped region into two portions. Thereafter, a third doped region of the second conductive type is formed in the semiconductor substrate at a bottom of the cave. Subsequently, according to another embodiment of the present invention, before the thinning step is performed in the fabricating method, two second doped columns of the second conductive type are formed. Each second doped column extends from an opposite surface of the semiconductor substrate toward the first surface. Moreover, each first trench is formed in the semiconductor substrate between the two second doped columns. After the thinning step is performed, fourth doped regions of the first conductive type are formed on the second surface of the semiconductor substrate at both sides of the first trench respectively. Each fourth doped region connects to the respective second doped column. Further, according to an embodiment of the present invention, in the formation of the second doped columns, two third trenches are formed in the semiconductor substrate. Next, the third trenches are filled with the epitaxial material of the second conductive type.

According to an embodiment of the present invention, in the step of forming the caves, a spacer is formed on a sidewall of the first trench to cover a partial surface of the first doped region. Next, the caves are formed on the bottoms of the first trenches by using the spacers as masks. In addition, according to another embodiment of the present invention, a passivation layer is formed on a surface of each third doped region before the fourth doped regions are formed. The passivation layers are removed after the fourth doped regions are formed.

According to an embodiment of the present invention, in the method of fabricating the semiconductor device, the first trench is filled with a filling material after the first trenches are formed and before the thinning step is performed. Thereafter, the filling material is removed after the thinning step is performed and before the first doped regions are formed.

In the method of fabricating the semiconductor device of the present invention, a simple fabricating method can be utilized to fabricate a device with low contact resistance and low on-state resistance while preventing the deformation of the chip during the fabrication process.

In order to make the aforementioned and other features and advantages of the present invention more comprehensible, several embodiments accompanied with figures are described in detail below.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIGS. 1A through 1D are schematic cross-sectional views illustrating a fabrication method of a planar field effect transistor device according to an embodiment of the present invention.

FIGS. 11A-1 through 1D-1 are schematic cross-sectional views illustrating a fabrication method of a trench field effect transistor device according to an embodiment of the present invention.

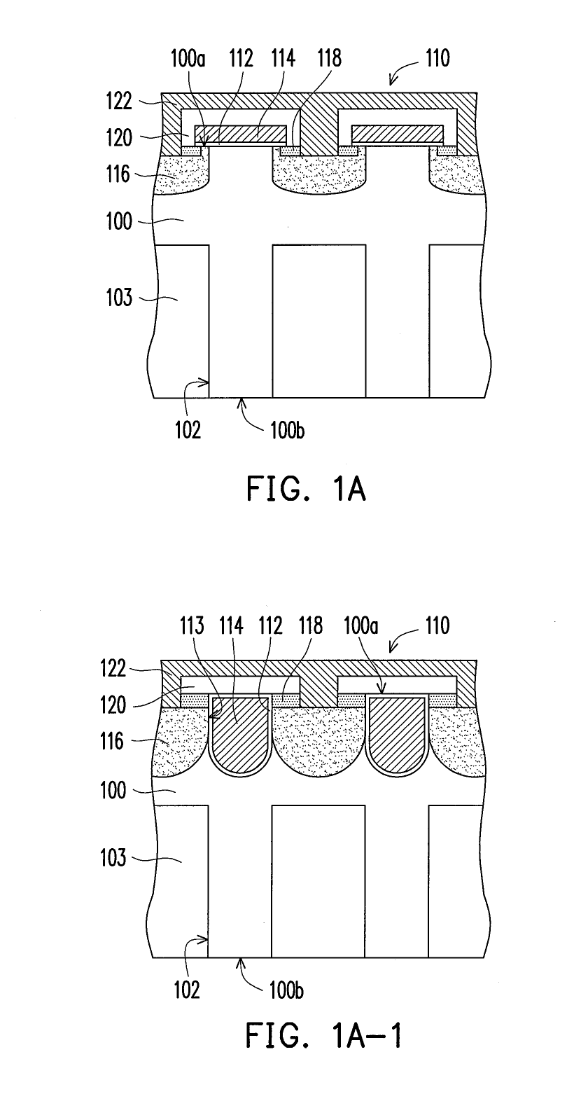

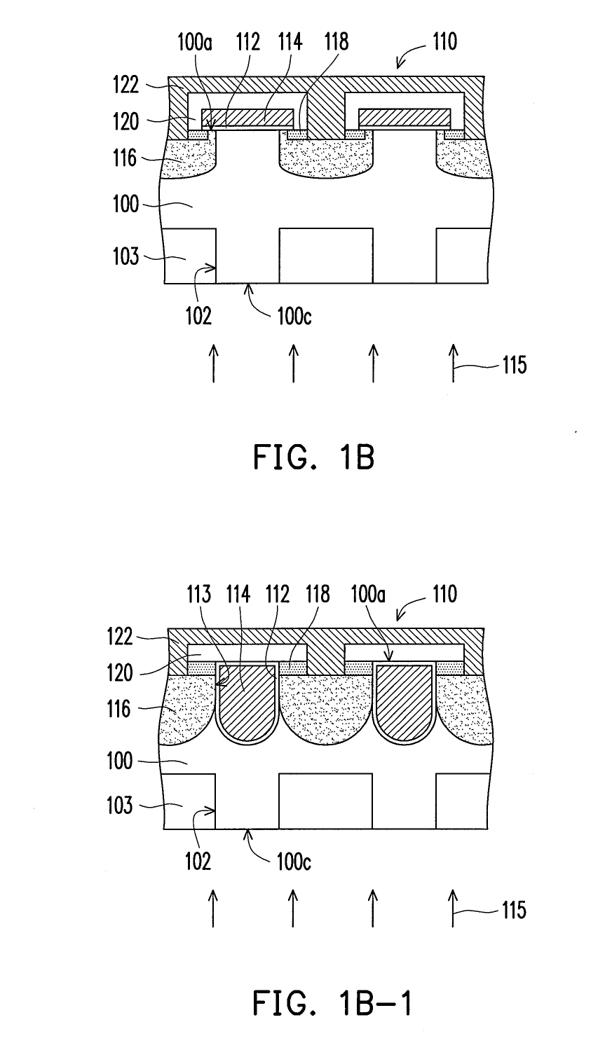

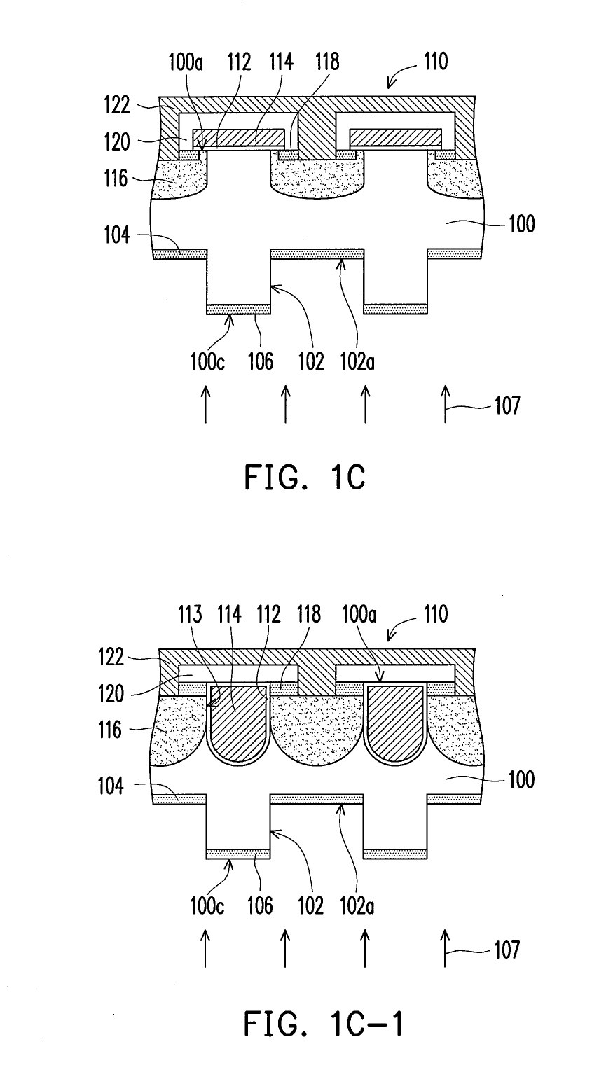

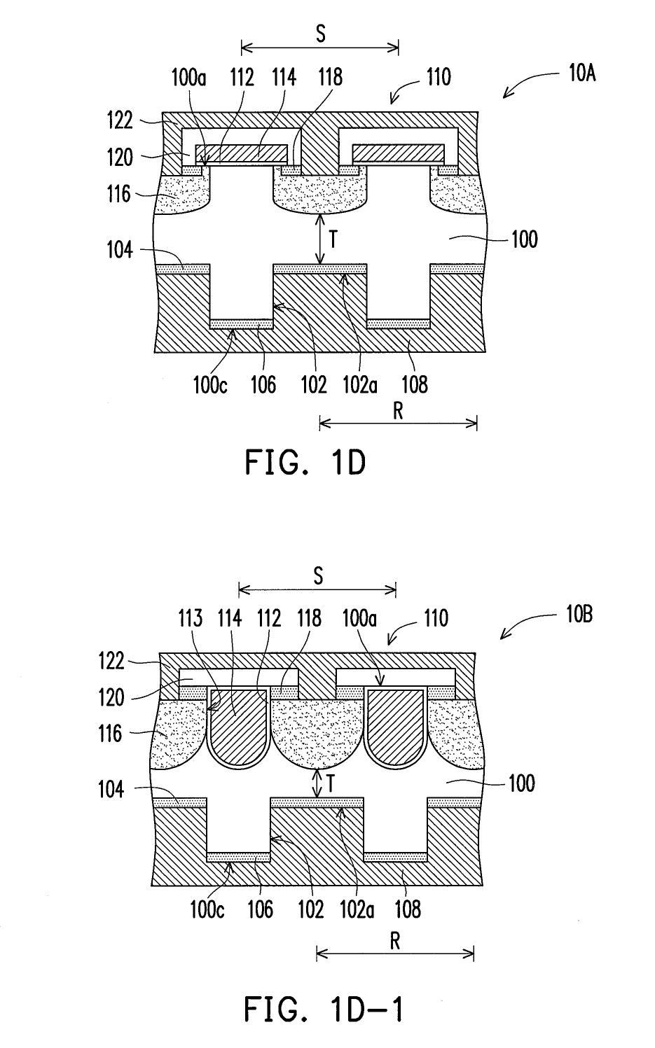

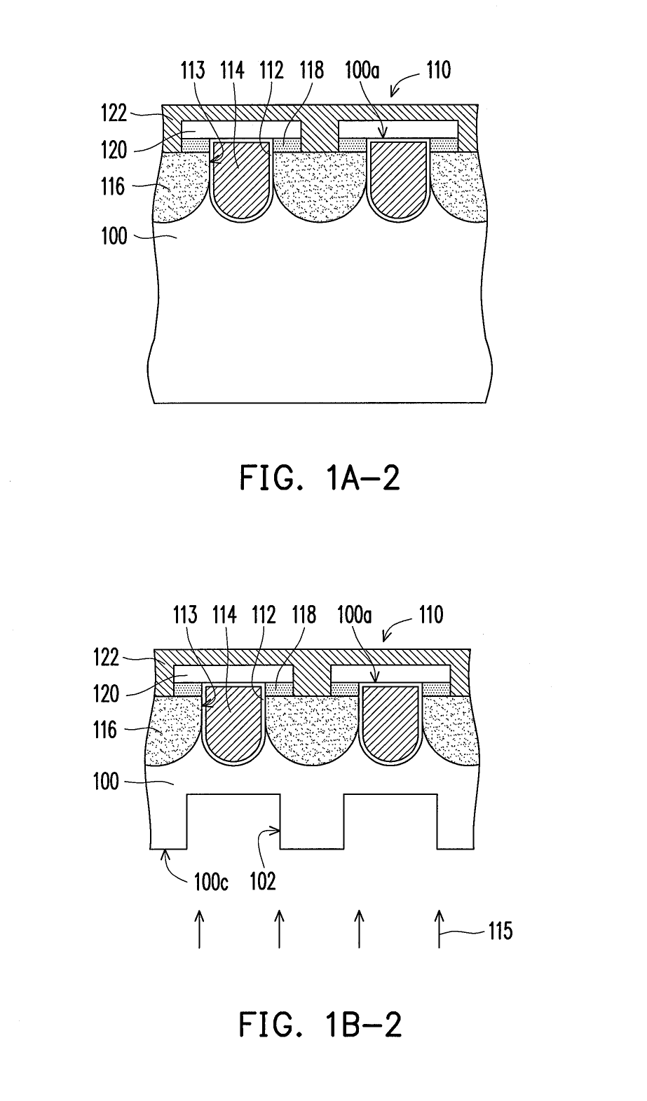

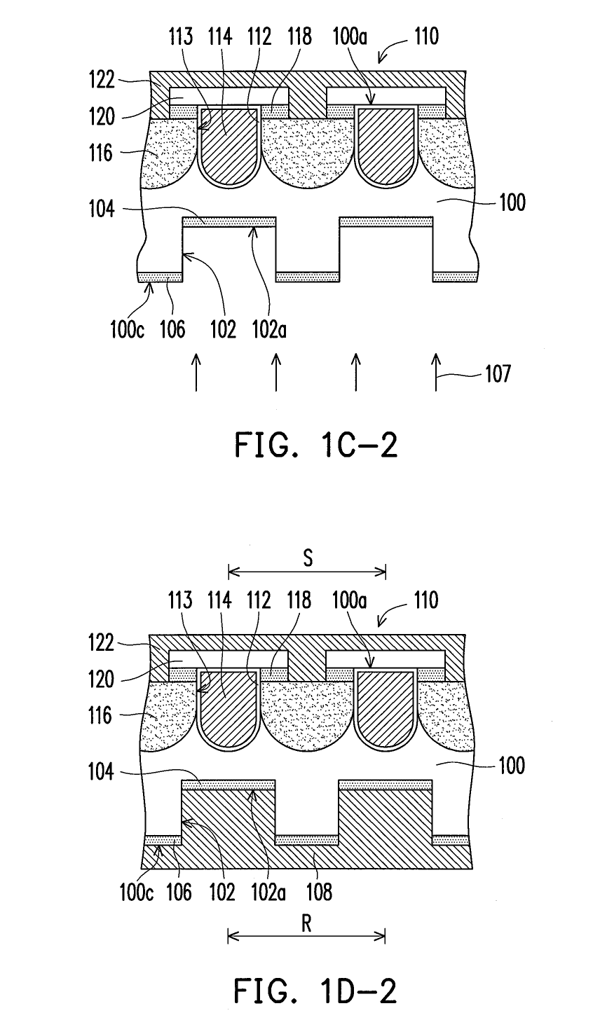

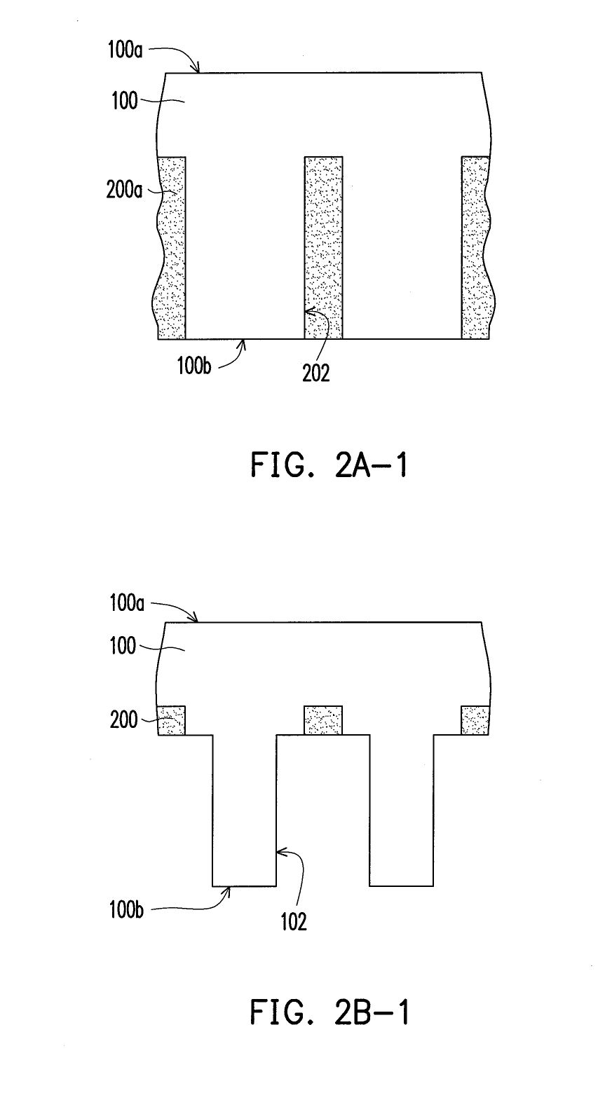

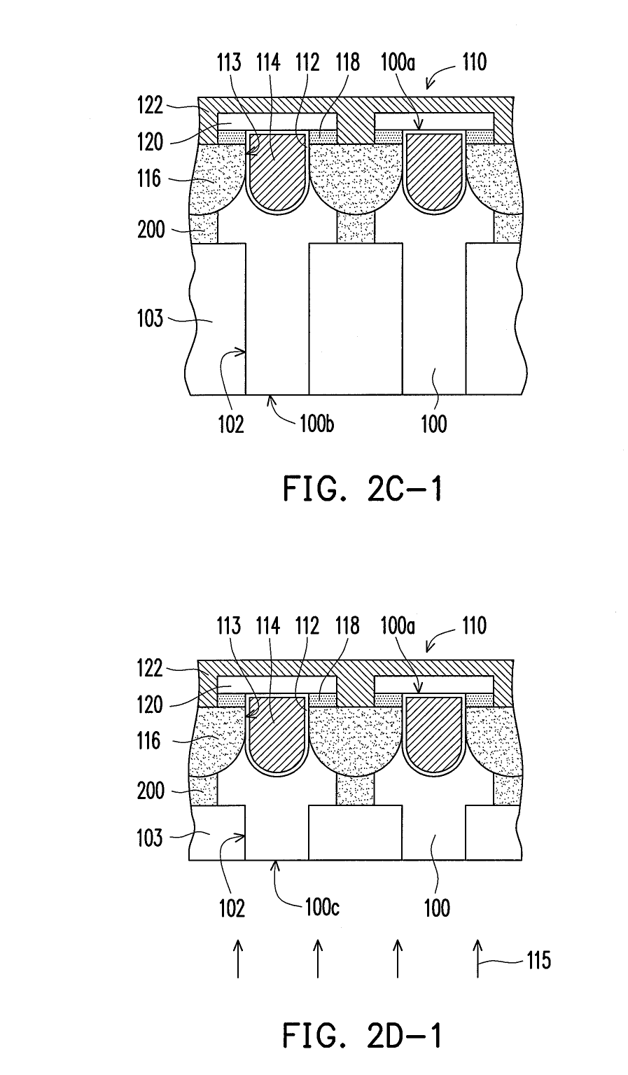

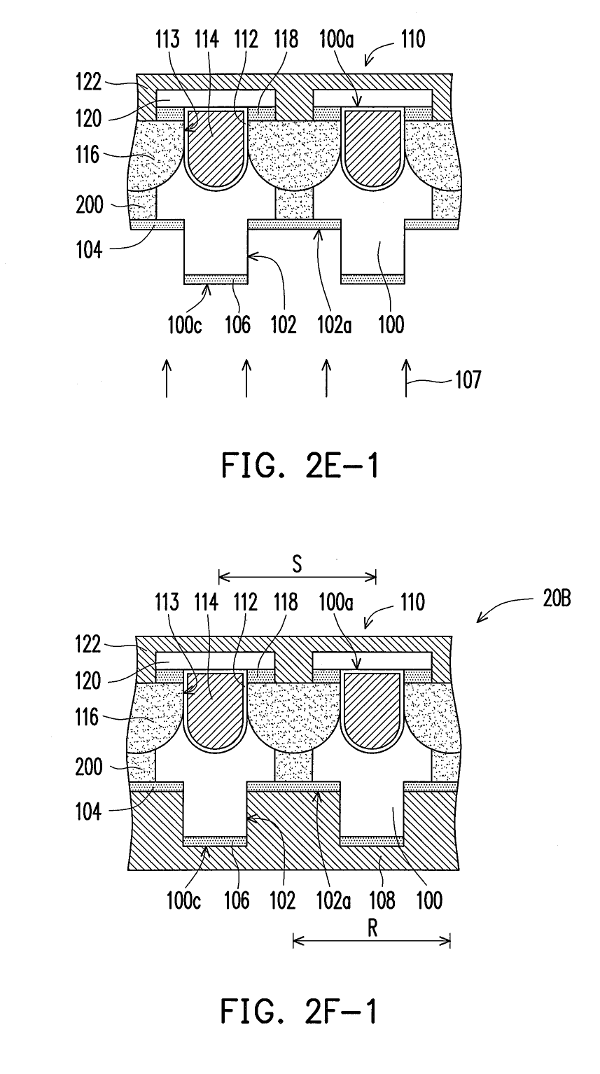

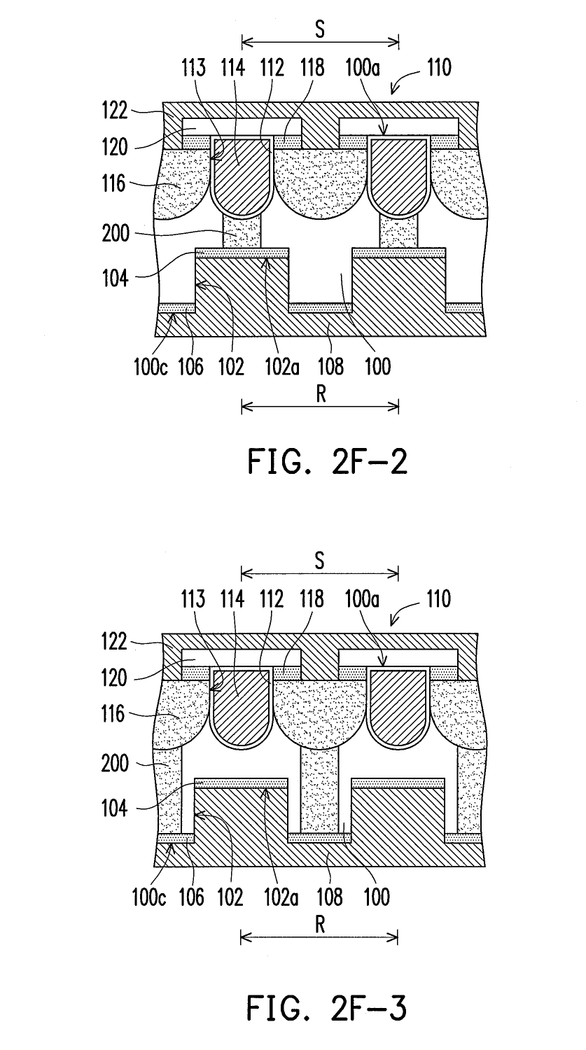

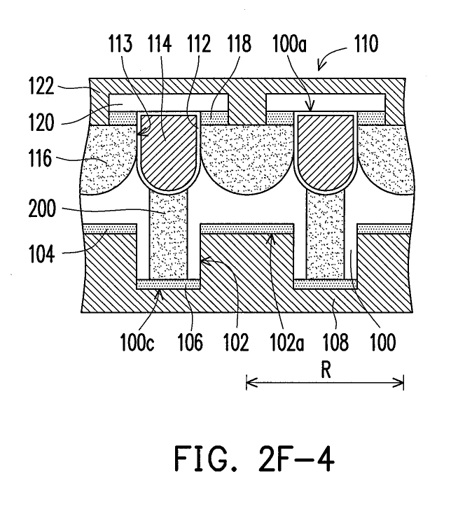

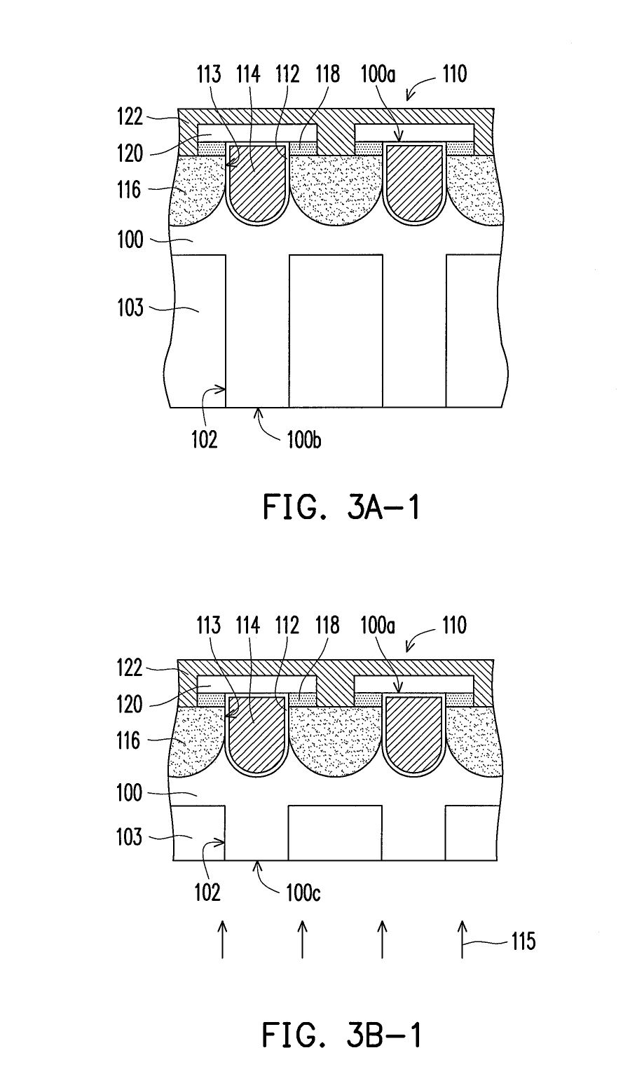

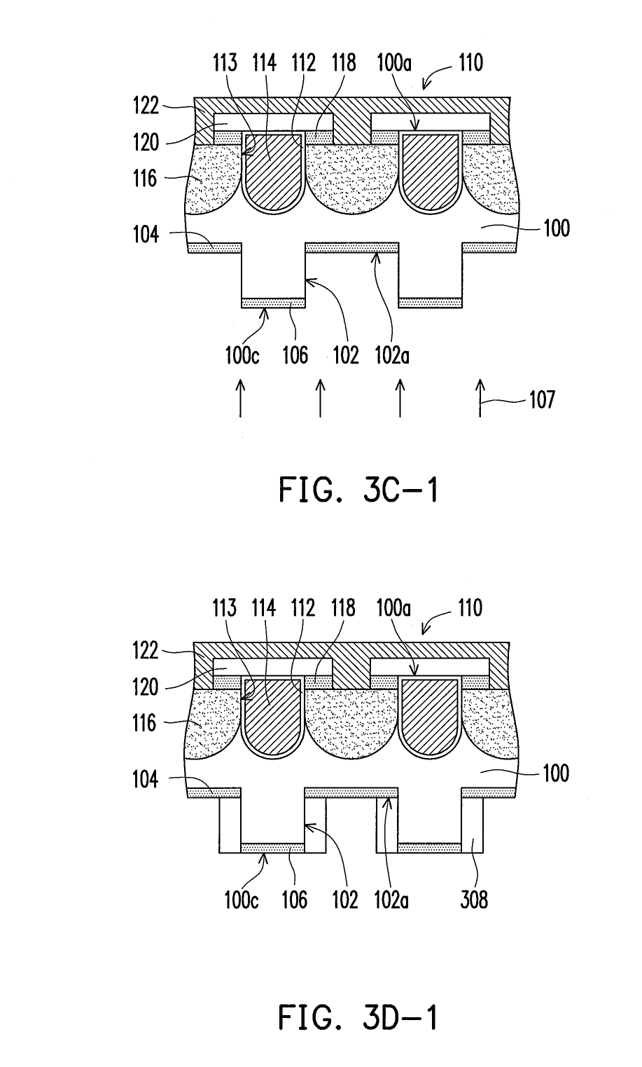

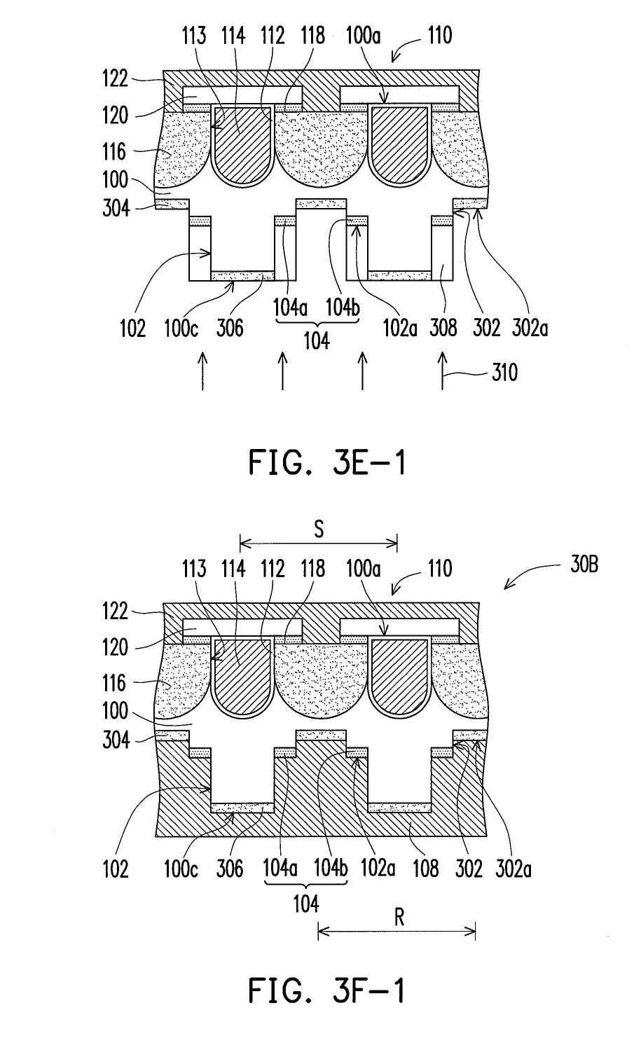

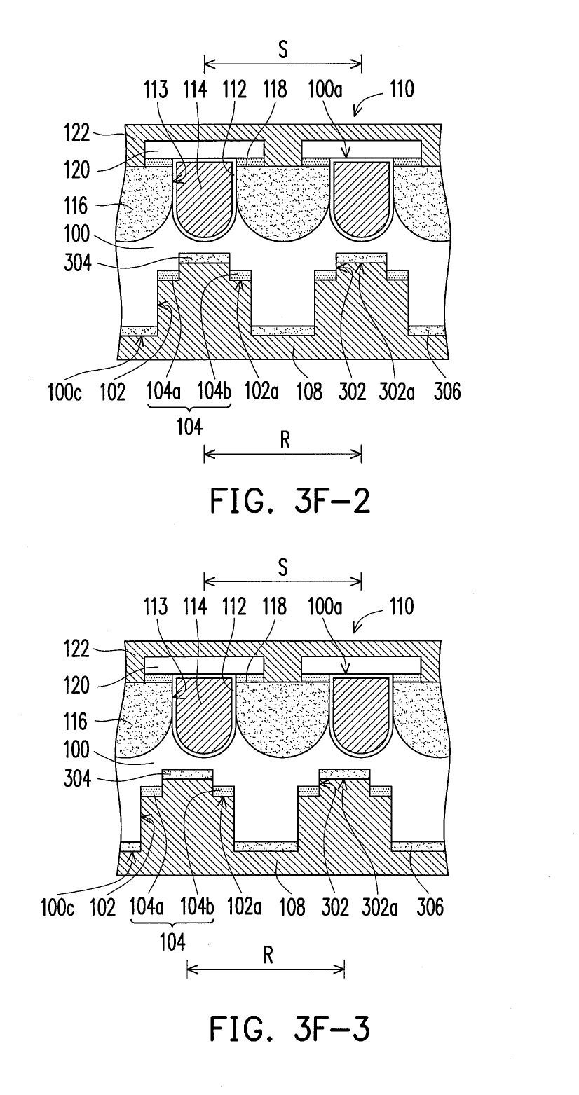

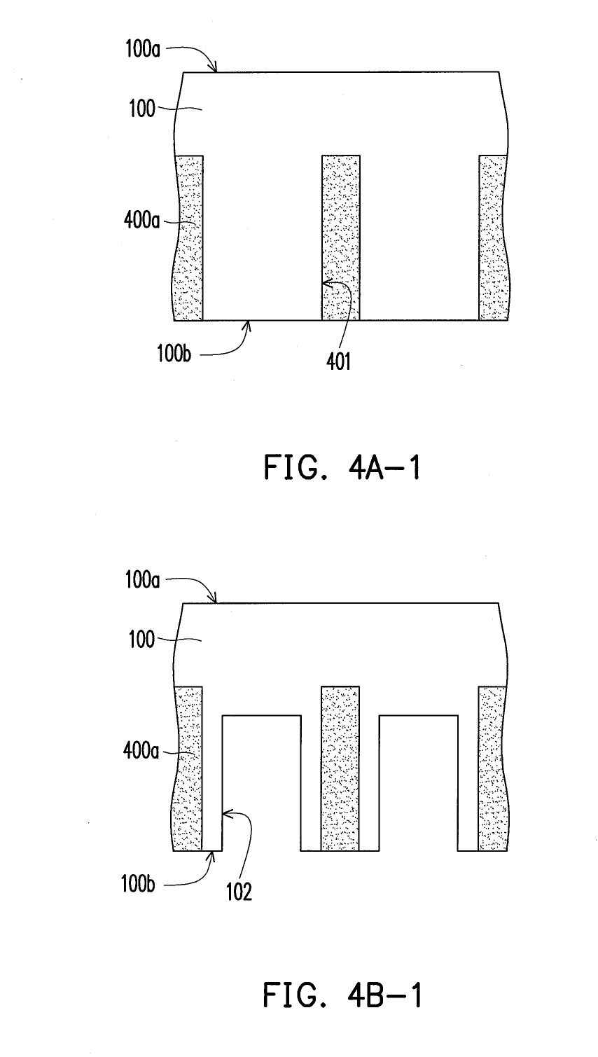

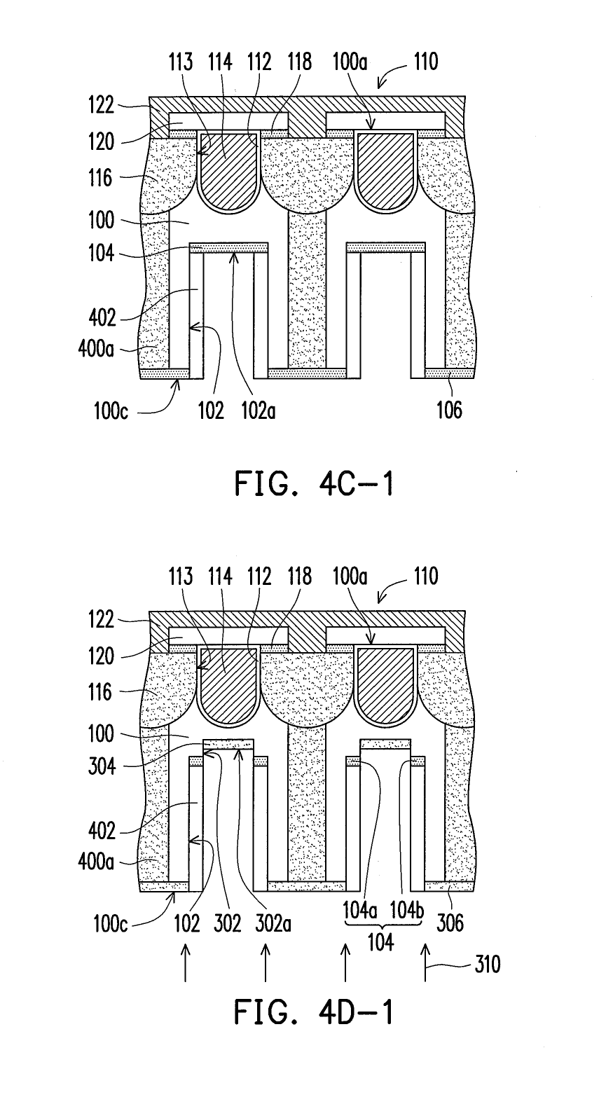

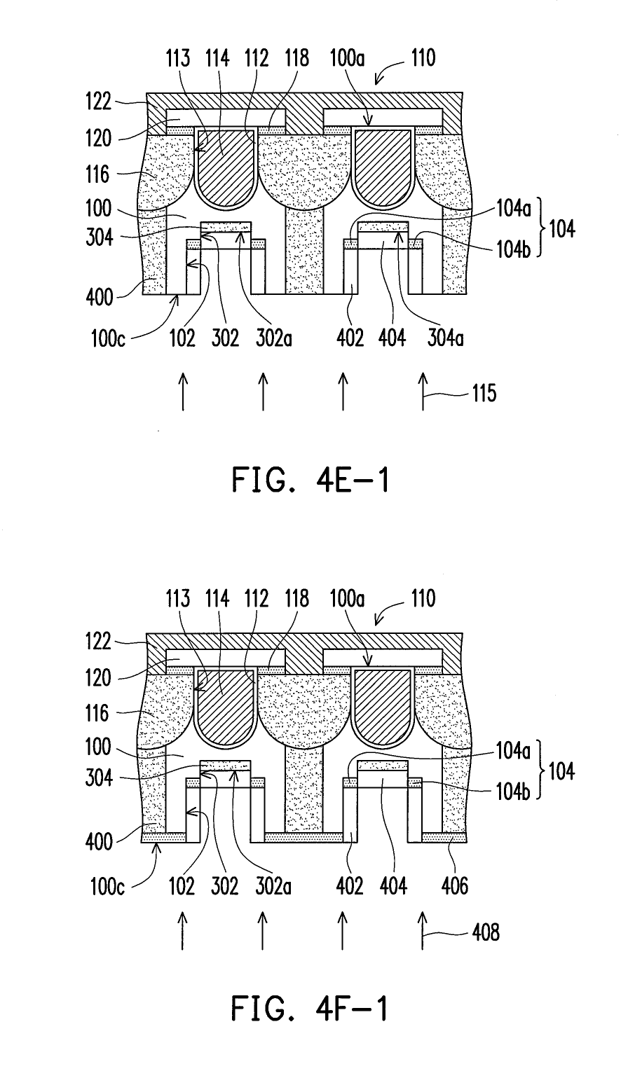

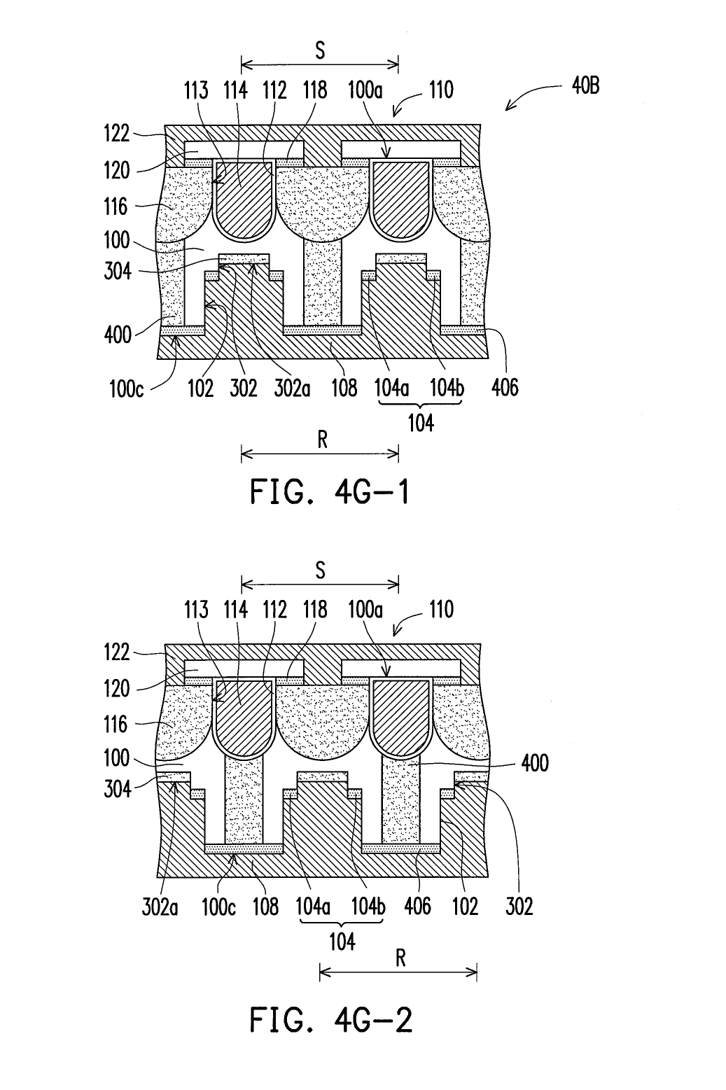

FIGS. 1A-2 through 1D-2 are schematic cross-sectional views illustrating a fabrication method of another trench field effect transistor device according to an embodiment of the present invention.

FIGS. 2A-1 through 2F-1 are schematic cross-sectional views illustrating a fabrication method of a trench super junction field effect transistor device according to an embodiment of the present invention.

FIGS. 2F-2, 2F-3, 2F-4 are schematic cross-sectional views illustrating a number of trench super junction field effect transistor devices according to an embodiment of the present invention.

FIGS. 3A-1 through 3F-1 are schematic cross-sectional views illustrating a fabrication method of a trench super junction field effect transistor device according to an embodiment of the present invention.

FIGS. 3F-2, 3F-3 are schematic cross-sectional views illustrating two trench super junction field effect transistor devices according to other embodiments of the present invention.

FIGS. 4A-1 through 4G-1 are schematic cross-sectional views illustrating a fabrication method of a trench semiconductor device combining a super junction metal oxide semiconductor transistor device and an IGBT according to an embodiment of the present invention.

FIGS. 4G-2 is a schematic cross-sectional view illustrating another trench semiconductor device combining a super junction metal oxide semiconductor transistor device and an IGBT according to another embodiments of the present invention.

### DESCRIPTION OF EMBODIMENTS

FIGS. 1D and 1D-1 are schematic cross-sectional views of a planar field effect transistor device and a trench field effect transistor device according to an embodiment of the present invention.

Referring to FIGS. 1D and 1D-1, both the planar field effect transistor device 10A and the trench field effect transistor device 10B include a semiconductor substrate 100, doped regions 104, doped regions 106, an electrical contact layer 108, and metal oxide semiconductor (MOS) cells 110.

The semiconductor substrate 100 is composed of single crystal silicon or the like, for example. The semiconductor substrate 100 is doped with a first conductive type dopant. The first conductive type dopant may be an n-type dopant, such as phosphorus and arsenic, or a p-type dopant, such as boron. A dopant concentration of the semiconductor substrate 100 is adjusted according to the characteristics or size of the device for example.

The semiconductor substrate 100 includes a plurality of separated trenches 102 extending from a surface 100c of the semiconductor substrate 100 to the interior portions thereof. A depth and a width of the trench 102 can be adjusted according to the requirements.

According to one embodiment of the present invention, a thickness of the semiconductor substrate 100 is approximately 200˜300 μm. For the MOSFET device with a withstand voltage of 100 volts, a material of 1.8˜2.5 ohms-cm can be selected as the semiconductor substrate 100. The depth of the trench 102 is determined according to the withstand voltage of the planar field effect transistor device 10A. That is, the higher the withstand voltage is, the shallower the trench 102 is formed.

The doped region 104 is located in the semiconductor substrate 100 under a bottom 102a of the trench 102 as a drain doped region. A dopant concentration of the doped region 104 is higher than that of the semiconductor substrate 100. In one embodiment, the dopant concentration of the doped region 104 is within the range of 1×10¹⁵˜4×10¹⁵ 1/cm³.

In the present embodiment, the doped region 106 is located in the surface 100c of the semiconductor substrate 100 at both sides of each trench 102. The doped regions 104 and the doped regions 106 are formed in the semiconductor substrate 100 in the same ion implantation process.

The electrical contact layer 108 is located on the surface 100c of the semiconductor substrate 100. The electrical contact layer 108 directly contacts with the doped regions 104 and doped regions 106. A material of the electrical contact layer 108 is a conductive material including metals, such as gold, aluminum, or aluminum alloy. In the present embodiment, the electrical contact layer 108 acts as a drain contact layer.

The metal oxide semiconductor cells 110 of the planar field effect transistor device 10A or the trench field effect transistor device 10B are located on the surface 100a of the semiconductor substrate 100. A pitch S between the metal oxide semiconductor cells 110 is no greater than a distance R between the neighboring trenches 102. In the present embodiment, each metal oxide semiconductor cell 110 includes a gate 114, a gate dielectric layer 112, a doped region 118, a well 116, an electrical contact layer 122, and an insulating layer 120.

In the embodiment shown in FIG. 1D, the gates 114 of the metal oxide semiconductor cells 110 are located on the surface 100a of the semiconductor substrate 100. In another embodiment, referring to FIG. 1D-1, the gates 114 of the metal oxide semiconductor cells 110 are located in the trenches 113 of the semiconductor substrate 100.

Referring to FIGS. 1D and 1D-1, the gates 114 and the trenches 102 are alternatively arranged. However, the present invention is not limited thereto. The gates 114 and the trenches 102 can also be oppositely arranged as shown in FIG. 1D-2. Moreover, the arrangement of the trenches 102 can be irrelevant with the gates 114 of the metal oxide semiconductor cells 110. The gates 114 is a doped polycrystalline silicon layer or a combination of the doped polycrystalline silicon layer and a metal silicide layer, for example.

The gate dielectric layer 112 is disposed between the gate 114 and the semiconductor substrate 100. The gate dielectric layer 112 may be composed of silicon oxide, silicon nitride, or high dielectric constant (k) materials with a dielectric constant higher than 4.

The wells 116 are located in the semiconductor substrate 110 at the both sides of the gate 114. In FIG. 1D and FIG. 1D-1, the well 116 and the trench 102 are oppositely arranged but separated with each other by a distance T. The wells 116 and the trenches 102 can also be alternately arranged also. The wells 116 is doped with the second conductive type dopant. The second conductive type and the first conductive type are different.

The doped regions 118 are located in the wells 116 and adjacent to the sidewalls of the gates 114. A conductive type of the doped regions 118 is the same as that of the doped regions 104. In the present embodiment, the doped regions 118 act as the source doped regions.

The electrical contact layer 122 is located on the surface 100a of the semiconductor substrate 100. The electrical contact layer 122 is directly contacted with the doped regions 118 and the wells 116 and electrically connected thereto. The electrical contact layer 122 is composed of a conductive material such as gold, aluminum, or aluminum alloy. In the present embodiment, the electrical contact layer 122 acts as a source contact layer.

The insulating layer 120 is disposed between the electrical contact layer 122 and the gate 114. The insulating layer 120 is composed of silicon oxide, borophosphosilicate glass (BPSG), phosphosilicate glass (PSG), fluorosilicate glass (FSG), undoped silicon glass (USG), or the other dielectric materials with a dielectric constant lower than 4.

In addition, because the field effect transistor device is formed on a lightly-doped semiconductor substrate directly, the formation of an epitaxial layer on the semiconductor substrate is not needed in the present invention. Thus, the time and cost of the epitaxial process can be reduced. Moreover, through the formation of trenches, on-state resistance of the field effect transistor device in the aforementioned embodiment can be adjusted and the structural strength of the semiconductor substrate can be maintained simultaneously to prevent the deformation of the semiconductor substrate.

The aforementioned field effect transistor devices can be fabricated by the methods presented in the following embodiments. However, the present invention is not limited thereto.

FIGS. 1A through 1D and FIGS. 1A-1 through 1D-1 are schematic cross-sectional views illustrating the fabrication method of a planar field effect transistor device and a trench field effect transistor device according to an embodiment of the present invention respectively.

Referring to FIG. 1A and FIG. 1A-1, a semiconductor substrate 100 of a first conductive type is provided. The semiconductor substrate 100 has a surface 100a and an opposite surface 100b. Next, trenches 102 are formed in the semiconductor substrate 100. Thereafter, a filling structure 103 is formed in the trenches 102. The filling structure 103 may be composed of an insulating material, such as silicon oxide, silicon nitride, or other suitable materials. As to the formation of the filling structure 103, the trenches are filled with a filling material by using chemical vapor deposition (CVD) technology first, and then the filling material outside of the trenches 102 are removed by etching or chemical-mechanical polishing. If the semiconductor substrate 100 having the trenches 102 formed thereon is available, only the step of forming the filling structure 103 in the trenches 102 has to be performed.

Then, referring to 1A, a plurality of metal oxide semiconductor cells 110 are formed on the surface 100a of the semiconductor substrate 100. The metal oxide semiconductor cell 110 of the flat field effect transistor includes a gate 114, a gate insulating layer 112, doped regions 118 of the first conductive type, wells 116 of the second conductive type, an electrical contact layer 122, and an insulating layer 120. The metal oxide semiconductor cells 110 of the planar field effect transistor device may be fabricated by using the following steps. Firstly, the gate dielectric layers 112 and the gates 114 are formed on the surface 100a of the semiconductor substrate 100. Subsequently, the wells 116 are formed in the semiconductor substrate 100 at the both sides of the gates 114. It is obvious that the well 116 can be formed before the formation of the gate dielectric layers 112 and the gates 114. Afterward, the doped regions 118 are formed in the wells 116 at the both sides of the gates 114. The doped regions 118 may be fabricated by implanting the first conductive type dopants into the semiconductor substrate 100 by using an ion implantation process. Thereafter, the insulating layer 120 is formed on the surface 100a of the semiconductor substrate 100. Then, the insulating layer 120 and a portion of the semiconductor substrate 100 are etched so as to form contact openings 121 in the insulating layer 120 to expose the wells 116. Thereafter, the electrical contact layer 122 is formed on the surface 100a of the semiconductor substrate 100. The electrical contact layer 122 is electrically connected with the doped regions 118 and the wells 116. The electrical contact layer 122 may be composed of a conductive material such as metal and fabricated by using physical vapor deposition (PVD) process such as sputtering or evaporation. Referring to FIG. 1A-1, in another embodiment, the metal oxide semiconductor cell 110 of the trench field effect transistor includes a gate 114, a gate insulating layer 112, doped regions 118 of the first conductive type, wells 116 of the second conductive type, an electrical contact layer 122, and an insulating layer 120. A difference between the fabricating methods of the trench field effect transistor device and the planar field effect transistor device is that the gates 114 are formed inside the semiconductor substrate 100 in the trench field effect transistor device. That is, the trenches 113 are firstly formed in the semiconductor substrate 100, and then after the gate dielectric layer 112 is formed on sidewalls and bottoms of the trenches 113, the gates 114 are formed by filling the trenches 113 with the conductive material.

The scope of the present invention is not restricted by the locations of the gates 114 and the trenches 102, they can be arranged alternately, oppositely, or the arrangement of the trenches 102 can be irrelevant with the gates 114 of the metal oxide semiconductor cells 110. In addition, a pitch of the metal oxide semiconductor cells 110 does not need to be identical to a distance between the neighboring trenches 102. Hence, a great process margin is available in the process of forming the metal oxide semiconductor cells 110.

Afterwards, referring to FIGS. 1B and 1B-1, a thinning step 115 is performed for removing a thickness of the semiconductor substrate 100 from the opposite surface 100b thereof so as to form another surface 100c opposite to the surface 100a. The thinning step 115 is performed through grinding, for example. The thickness removed in the thinning step 115 is determined in accordance with the requirements. In one embodiment, if the thickness of the semiconductor substrate 100 to be formed is 300 μm and the thickness of the original semiconductor substrate 100 is 525 μm, a thickness of 225 μm is removed in the thinning step.

After, referring to FIG. 1C, the filling structure 103 is removed to expose the trenches 102. The filling structure 103 may be removed by using a wet etching process for example. Moreover, the doped regions 104 of the first conductive type are formed in the semiconductor substrate 100 under the bottom 102a of each trench 102. Simultaneously, the doped regions 106 of the first conductive type are formed on the surface 100c of the semiconductor substrate 100 at the both sides of the trenches 102. The doped regions 104 and 106 can be formed by using an ion implantation process to implant a first conductive type dopant (the ion implantation direction is shown by label 107) is implanted into the semiconductor substrate 100. The dosage of the first conductive type dopant 107 is selected to make a dopant concentration of the doped regions 104 and 106 higher than that of the semiconductor substrate 100. The profile of the doped regions 104 and 106 are corresponding to the contours of the bottoms 102a of the trenches 102 and the surface 100c of the semiconductor substrate 100 respectively. In the present embodiment, the doped regions 104 are formed in the bottoms 102a of the trenches 102 and the locations of the trenches 102 are opposite to that of the wells 116. Therefore, the doped regions 104 are opposite to the wells 116. However, the doped regions 104 and the wells 116 are separated by a distance T, which determines a withstand voltage of the field effect transistor device. A value of the distance T can be manipulated through the depth of the trenches 102, a depth of the doped regions 104, or a depth of the wells 116 in accordance with the demands.

Thereafter, referring to FIG. 1D and FIG. 1D-1, an electrical contact layer 108 is formed on the surface 100c of the semiconductor substrate 100 and in the trenches 102. The electrical contact layer 108 is electrically connected to the doped regions 104 and 106 to complete the manufacture of the planar field effect transistor device 10A and the trench field effect transistor device 10B. A material of the electrical contact layer 108 may be selected from the conductive materials such as metal and formed by using PVD, such as sputtering or evaporation.

In the above method, the trenches 102 are firstly formed in the semiconductor substrate 100, and the filling structure 103 is filled into the trenches 102. After the metal oxide semiconductor cells 110 are formed on the semiconductor substrate 100, the thinning step 115 is performed. However, the scope of the present invention is not limited thereto. As the semiconductor substrate 100 with the trenches 102 being formed therein has enough strength to withstand the following fabrication steps, the step of forming the filling structure 103 can be skipped.

For simplifying the illustration, only the trench semiconductor device is described in the following. However, the present invention is not limited thereto, and the fabricating method can also be applied in the planar semiconductor device.

FIGS. 1A-2 through 1D-2 are schematic cross-sectional views illustrating a fabrication method of another trench field effect transistor device according to an embodiment of the present invention.

As shown in FIG. 1A-2, the metal oxide semiconductor cells 110 are formed first, and then the thinning step 115 is performed. Afterward, the trenches 102 are formed in the semiconductor substrate 100. However, as shown in FIG. 1B-2, there is no filling structure being formed in the trenches 102. Then, referring to FIGS. 1C-2 to 1D-2, the doped region 104 of the first conductive type is formed in the semiconductor substrate 100 at the bottom 102a of the trench 102. Simultaneously, the doped regions 106 of the first conductive type are formed on the surface 100c of the semiconductor substrate 100 at the both sides of the trenches 102. The detail process described in the above mentioned embodiment can be adopted in the present embodiment and thus is not repeated herein.

In addition, because the field effect transistor device is formed on a lightly-doped semiconductor substrate directly and the contact resistance between the electrical contact layer 108 and the semiconductor substrate 100 can be achieved through the heavily-doped doped region 104, the formation of an epitaxial layer on the semiconductor substrate is not needed and the time and cost of the epitaxial process can be reduced.

Besides, the distance T between the doped regions 104 and the wells 106 can be adjusted through the depth of the trenches 102, the depth of the doped regions 104, or the depth of the wells 116 without the need of manipulating the thickness of the epitaxial layer. Moreover, as the distance T has to be increased for providing a greater withstand voltage, the depth of the trenches 102 is reduced and thus the fabricating process is easier. In contrast with the prior art, the thickness of the epitaxial layer has to be increased for providing a greater withstand voltage. Hence, the embodiment of the present invention not only simplifies the process but also reduces the fabricating cost. Additionally, the bending deformation of the semiconductor substrate due to the inner stress generated from an over-thick epitaxial layer is also prevented.

FIGS. 2F-1 through 2F-4 are schematic cross-sectional views illustrating a number of trench super junction field effect transistor devices according to an embodiment of the present invention.

Referring to FIG. 2F-1, a structure of a trench super junction field effect transistor device 20B is similar to that of the trench field effect transistor device 10B in FIG. 1D-1. A major difference between the two structures is that the trench super junction field effect transistor device 20B of the present embodiment has doped columns 200, and a conductive type of the doped column is the same as that of the wells 116.

The doped columns 200 are composed of epitaxial polysilicon for example. The scope of the present invention is not restricted by the relative positions of the trenches 102, the gates 114, and the doped columns 200, and the following embodiment is merely an example of the present invention.

In the embodiment in FIG. 2F-1, the trenches 102 and the gates 114 are alternately arranged and the doped columns 200 are located in the semiconductor substrate 100 between the doped regions 104 and the wells 116. One end of the doped column 200 is connected to the respective doped region 104. The other end of the doped column 200 is aligned to the respective well 116. The doped columns 200 are electrically connected to the wells 116 or separated from the wells 116 by a small distance. A width of the doped column 200 is smaller than that of the respective trench 102.

Referring to FIG. 2F-2, in another embodiment, the trenches 102 and the gates 114 are oppositely arranged. The doped columns 200 are located in the semiconductor substrate 100 between the doped regions 104 and the gates 114. One end of the doped column 200 is connected to the respective doped region 104. The other end of the doped column 200 is aligned to the respective gate 114. Moreover, the doped columns 200 are separated from the gates 114 by a small distance. A width of the doped columns 200 is smaller than that of the bottoms of the respective trenches 102.

Since the conductive type of the doped columns 200 is different from that of the semiconductor substrate 100, when the device is operated under reverse bias, a depletion region is formed at the interface between the semiconductor substrate 100 and the doped columns 200 under the gates 114 so as to enhance the withstand voltage.

FIGS. 2A-1 through 2F-1 are schematic cross-sectional views illustrating a fabrication method of a trench super junction field effect transistor device according to an embodiment of the present invention.

Referring to FIG. 2F-1, a fabricating method of the trench super junction field effect transistor device 20B is similar to that of the trench field effect transistor device 10B in FIG. 1D-1. A major difference between the two embodiments is the generation of the doped columns 200.

Referring to FIGS. 2A-1 and 2B-1, the doped columns 200 is formed in the semiconductor substrate 100 before the trenches 102 are formed. The doped columns 200 extend from the opposing surface 100b of the semiconductor substrate 100 to the interior portions thereof. The doped columns 200 may be formed by forming trenches 202 in the semiconductor substrate 100 and then filling the trenches 202 with an epitaxial material 202a of the second conductive type. A depth of the trenches 202 is deeper than that of the trenches 102 (as shown in FIG. 2B-1) formed subsequently. After the trenches 102 are formed in the semiconductor substrate 100, the remaining epitaxial material in the trenches 202 becomes the doped columns 200 as shown in FIG. 2B-1. The following steps as illustrated in FIGS. 2B-1 through 2F-1 are similar to that of the embodiments aforementioned and thus are not repeated herein.

In addition, the above mentioned embodiment is related to the fabricating method of the super junction field effect transistor device 20B as shown in FIG. 2F-1. However, the super junction field effect transistor device 20B in FIGS. 2F-2 through 2F-4 can be formed by using a similar method with only the relative positions being adjusted.

FIGS. 3F-1 is a cross-sectional view illustrating a trench IGBT according to an embodiment of the present invention.

A major difference between a structure of a trench IGBT 30B and the structure of the field effect transistor device 10B in FIG. 1D-1 is that the structure of the trench IGBT 30B includes caves 302 in the semiconductor substrate 100 under the bottoms of the trenches 102. A width of the caves 302 is smaller than that of the trenches 102. The cave 302 divides the respective doped region 104 into two portions 104a and 104b. Additionally, doped regions 304 of the second conductive type, which is different from that of the doped region 104, are formed in the semiconductor substrate 100 at the bottoms 302a of the caves 302. The doped regions 304 and the wells 116 are oppositely arranged and separated by a distance.

Similarly, the positions of the gates 114 and the trenches 102 of the present embodiment are not meant to restrict the present invention. Referring to FIGS. 3F-1, 3F-2, and 3F-3, the gates 114 and the trenches 102 can be alternately arranged, oppositely arranged, or the positions of the gates 114 can be irrelevant with that of the trenches 102, respectively.

The electrical contact layer 108 is referred as a collector of the IGBT 30B and the electrical contact layer 122 is referred as an emitter. Since the doped regions 104a, 104b, and 304 are doped with high concentration dopants, low resistance ohmic contact with is formed between the doped regions 104a and the electrical contact layer (collector) 108, between the doped regions 104b and the electrical contact layer (collector) 108, and between the doped regions 304 and the electrical contact layer (collector) 108. In addition, the trench IGBT 30B of the present embodiment is formed on the lightly-doped semiconductor substrate 100 just like the field effect transistor devices in the aforementioned embodiments. The epitaxial layer is not needed in the trench IGBT 30B and the time and cost required for the epitaxial process are reduced.

Furthermore, as illustrated in FIGS. 3F-1, 3F-2, and 3F-3, there is a diode between the well 116 and the doped regions 104a, 104b connected to the IGBT in parallel.

FIGS. 3A-1 through 3F-1 are schematic cross-sectional views illustrating the fabrication method of a trench super junction field effect transistor device according to an embodiment of the present invention.

In the present embodiment, as shown in FIGS. 3A-1 to 3C-1 the, fabrication steps of the trench IGBT 30B before the formation of the electric contact layer 108 are identical to that of the trench field effect transistor device 10B as shown in FIGS. 1A-1 to 1C-1, thus is not repeated herein.

Referring to FIG. 3D-1, after the doped regions 104 and 106 are formed, a spacer 308 is formed on a sidewall of each trench 102 for covering a portion the doped region 104. A material of the spacers 308 is different from that of the semiconductor substrate 100. For example, an insulating material, such as silicon oxide, silicon nitride, or the like, with high etching selectivity relative to the semiconductor substrate 100 can be selected. In a step of forming the spacers 308, the CVD process is adopted to form the insulating layer on the surface 100c, for example, and then an isotropic etching process is performed.

Subsequently, referring to FIG. 3E-1, the spacers 308 are used as etching masks for etching the semiconductor substrate 100 so as to form the caves 302 in the bottoms 102a of the trenches 102 to separate the doped region 104 into two portions 104a and 104b. The etching step can adopt an anisotropic etching technology. Next, an ion implantation process 310 is carried out for forming the doped regions 304 of the second conductive type in the semiconductor substrate 100 at the bottoms 302a of the caves 302. Afterwards, the electrical contact layer 108 is formed as shown in FIG. 3F-1 to complete the fabrication of the trench IGBT 30B.

The fabricating method of the trench IGBT 30B in the present embodiment may adopt the fabrication steps as shown in FIGS. 1A-2 through 1C-2 before the formation of the electrical contact layer 108.

The fabricating method of the trench IGBT 30B provided in the present embodiment has the advantages as the fabricating method of the trench field effect transistor device 10B. In addition, the diode connected to the IGBT in parallel is formed merely through the formation of the caves and the ion implantation process, and the fabricating process is quite simple.

FIG. 4G-1 is a cross-sectional view of the trench semiconductor device combining the super junction metal oxide semiconductor transistor and the IGBT according to an embodiment of the present invention. Referring to FIG. 4G-1, in the structure of the trench semiconductor device 40B, the gates 114 are opposite to the trenches 102, and the doped regions 406 are opposite to the wells 116.

In addition, in the trench semiconductor device 40B of the present embodiment, the caves 302 are formed in the semiconductor substrate 100 under the bottoms of the trenches 102. A width of the caves 302 is smaller than that of the trenches 102. Moreover, the cave 302 separates the doped region 104 into two portions 104a and 104b. The doped regions 304 are formed at the bottoms 302a of the caves 302. The conductive type of the doped regions 304 is the second conductive type, which is different from that of the doped region 104.

Moreover, the trench semiconductor device 40B of the present embodiment includes the doped columns 400. The doped columns 400 are of the second conductive type which is the same as that of the wells 116. On the other hand, the conductive type of the doped columns 400 is also different from that of the semiconductor substrate 100. The doped columns 400 are located in the semiconductor substrate 100 between the doped regions 106 and the wells 116. One end of the doped column 400 is connected to the doped region 106 and the other end is electrically connected to the well 116 or separated from the well 116 by a distance.

In another embodiment, referring to FIG. 4G-2, the gates 114 and the trenches 102 are arranged alternately. One end of each doped column 400 is connected to the doped region 406 and the other end is aligned to the gate 114.

In the present embodiment, the electrical contact layer 108 is referred as the collector and the electrical contact layer 122 is referred as the emitter. The electrical contact layer (collector) 108 is composed of a metal material. The doped regions 104a, 104b and the doped regions 304 are all of high dopant concentration. An ohmic contact is formed between the doped regions 104a and the electrical contact layer (collector) 108, between the doped regions 104b and the electrical contact layer (collector) 108, and between the doped regions 304 and the electrical contact layer (collector) 108. Moreover, as the conductive type of the doped columns 400 and that of the semiconductor substrate 100 are different. When the device is operated under reverse bias, a depletion region is formed between the semiconductor substrate 100 and the doped columns 400 under the gates 114 for enhancing the withstand voltage.

FIGS. 4A-1 through 4G-1 are schematic cross-sectional views illustrating a fabrication method of the trench semiconductor device combining the super junction metal oxide semiconductor transistor and the IGBT.

The fabricating method of the trench semiconductor 40B in the present embodiment is similar to the fabricating method of the trench field effect transistor device 10B in FIG. 1D-1. A major difference between the two embodiments is the formation of the doped columns 400.

Referring to FIG. 4A-1, the doped columns 400a are formed in the semiconductor substrate 100 before the trenches 102 are formed. In the step of forming the doped columns 400a, a deep trench 401 is firstly formed in the semiconductor substrate 100 and then epitaxial material of the second conductive type is filled into the deep trench 401. Then, referring to FIG. 4B-1, the trenches 102 are formed. In the present embodiment, the trenches 102 and that of the doped columns 400a are alternately arranged and are opposite to the gates 114 formed in the following step.

Thereafter, referring to FIG. 4C-1, the metal oxide semiconductor cells 110 are formed with the wells 116 thereof being electrically connected to the doped columns 400a. Next, the ion implantation process is performed to form the doped regions 104 of the first conductive type at the bottoms 102a of the trenches 102 and the doped regions 106 of the first conductive type in the surface 100b of the semiconductor substrate 100 at the both sides of the trenches 102. Afterward, a spacer 402 is formed on a sidewall of the trench 102 to cover a portion of the doped region 104. The spacer 402 is composed of an insulating material, such as silicon oxide, silicon nitride, or the like, which has high etching selectivity relative to the semiconductor substrate 100. This insulating material is silicon oxide, silicon nitride, or other materials with similar properties. The spacers 402 may be formed by applying CVD process, for example.

Referring to FIG. 4D-1, the spacers 402 are used as the etching masks for etching the semiconductor substrate 100 so as to form the caves 302 under the bottoms of the trenches 102 so separates the doped region 104 into two portions 104a and 104b. The etching step mentioned above can be performed by using an anisotropic etching process such as a dry etching. Afterward, the ion implantation process 310 is carried out to form the doped regions 304 of the second conductive type in the semiconductor substrate 100 at the bottoms 302a of the caves 302.

Then, referring to FIG. 4E-1, a passivation layer 404 is formed on a surface 304a of the doped region 304. The passivation layers 404 may fill the trenches 102 and the caves 302. A material of the passivation layers 404 may be an insulating material with high etching selectivity relative to the semiconductor substrate 100. The passivation layers by using CVD process, for example. Thereafter, a thinning step 115 is performed to form another surface 100c which is opposite to the surface 100b. This thinning step 115 removes the doped regions 306 located on the surface 100b and retains the doped columns 400. The thinning step 115 may be implemented by using a grinding process.

Next, referring to FIG. 4F-1, an ion implantation process 408 is performed to form the doped regions 406 on the surface 100c of the semiconductor substrate 100 at the both sides of the trenches 102. Subsequently, referring to FIG. 4G-1, the passivation layers 404 and the spacers 402 are removed by dry etching or wet etching. The electrical contact layer 108 is then formed to complete the manufacture of the trench semiconductor device 40B.

The embodiments aforementioned in the present invention can be applies to the power devices such as power supplies, rectifiers, low voltage motor controllers, and the like, but the present invention is not limited thereto. Devices with similar functions are also within the scope of the present invention.

In summary, the semiconductor devices of the above-mentioned embodiments in the present invention have the advantages of reducing on resistance of the device. In addition, the fabricating methods of the semiconductor devices are simplified in accordance with the present invention. This not only reduces the cost of the fabrication processes and the material, but also prevents the deformation of the chip in the fabricating process.

Although the present invention has been described with reference to the above embodiments, it will be apparent to one of the ordinary skill in the art that modifications to the described embodiment may be made without departing from the spirit of the invention. Accordingly, the scope of the invention will be defined by the attached claims not by the above detailed descriptions.

What is claimed is:

1. A semiconductor device, comprising:
a semiconductor substrate of a first conductive type, having a first surface and an opposing second surface and at least two first trenches extending from the second surface into interior portion thereof;
two separated first doped regions of the first conductive type, located in the semiconductor substrate under bottoms of the first trenches respectively, wherein a dopant concentration of the first doped regions is higher than a dopant concentration of the semiconductor substrate;
a first electrical contact layer, covering the first doped regions; and
at least a metal oxide semiconductor cell, located on the first surface of the semiconductor substrate.

2. The semiconductor device as claimed in claim 1, further comprising:
at least a second doped region of the first conductive type, located on the second surface, wherein a dopant concentration of the second doped region is higher than the dopant concentration of the semiconductor substrate.

3. The semiconductor device as claimed in claim 1, further comprising:
two first doped columns of a second conductive type, located in the semiconductor substrate, separated by a distance, connecting to the first doped regions respectively and extending to the metal oxide semiconductor cell.

4. The semiconductor device as claimed in claim 3, wherein each first doped column is formed by an epitaxial material.

5. The semiconductor device as claimed in claim 3, wherein the metal oxide semiconductor cell comprises a gate disposed on the first surface of the semiconductor substrate, and one of the first doped columns is aligned to the gate.

6. The semiconductor device as claimed in claim 3, wherein the metal oxide semiconductor cell comprises:
a gate, disposed on the first surface of the semiconductor substrate; and
two wells of the second conductive type, located in the semiconductor substrate at both sides of the gate, wherein the first doped columns are aligned to the wells.

7. The semiconductor device as claimed in claim 1, wherein the semiconductor substrate under the bottom of each first trench comprises a cave separating each first doped region into two portions, and further comprising:
two second doped regions of the second conductive type, located in a bottom of each cave, and separated from the metal oxide semiconductor cell.

8. The semiconductor device as claimed in claim 7, further comprising:
a third doped region of the first conductive type, wherein a dopant concentration of the third doped region is higher than the dopant concentration of the semiconductor substrate, and the third doped region is located on the second surface; and
two second doped columns of the second conductive type, located in the semiconductor substrate, connected to the third doped region and aligned to the metal oxide semiconductor cell.

9. The semiconductor device as claimed in claim 8, wherein the second doped columns are formed by an epitaxial material.

10. The semiconductor device as claimed in claim 8, wherein each metal oxide semiconductor cell comprises:
a gate, disposed on the first surface of the semiconductor substrate;
two wells of the second conductive type, located in the semiconductor substrate at both sides of the gate, wherein the second doped columns are aligned to the wells or aligned to each of the gates respectively.

11. A method of fabricating a semiconductor device, comprising:
providing a semiconductor substrate of a first conductive type, wherein the semiconductor substrate has a first surface and an opposing surface;
forming two separated first trenches in the semiconductor substrate, and the first trenches extending from the opposing surface into interior portion of the semiconductor substrate;
forming a first doped region of the first conductive type in the semiconductor substrate under a bottom of each first trench by using an ion implantation process, and a dopant concentration of each first doped region being higher than a dopant concentration of the semiconductor substrate;
forming at least a metal oxide semiconductor cell on the first surface of the semiconductor substrate;
thinning the semiconductor substrate by removing a thickness of the semiconductor substrate from the opposing surface to form a second surface; and
forming a first electrical contact layer covering the second surface of the semiconductor substrate and the first doped regions.

12. The method of fabricating the semiconductor device as claimed in claim 11, wherein the first doped regions are formed in the bottoms of the first trenches after the step of forming the metal oxide semiconductor cell and the step of thinning the semiconductor substrate.

13. The method of fabricating the semiconductor device as claimed in claim 11, wherein the first doped regions are formed in the bottoms of the first trenches before the step of forming the metal oxide semiconductor cell and the step of thinning the semiconductor substrate.

14. The method of fabricating the semiconductor device as claimed in claim 13, further comprising:
depositing a filling material in each first trench after the first trenches are formed and before the thinning step is performed; and
removing the filling material after the thinning step is performed and before the first doped regions are formed.

15. The method of fabricating the semiconductor device as claimed in claim 11, wherein in the step of forming the first doped regions, two second doped regions of the first conductive type are also formed on the opposing surface of the semiconductor substrate at the both sides of each first trench simultaneously.

16. The method of fabricating the semiconductor device as claimed in claim 11, wherein a pitch of the metal oxide semiconductor cells is no greater than a distance between two adjacent first trenches.

17. The method of fabricating the semiconductor device as claimed in claim 11, further comprising:
before the first trenches are formed, forming two first doped columns of a second conductive type extending from the opposing surface of the semiconductor substrate toward the first surface, wherein the first trenches align to the first doped columns respectively and a width of the first trench is greater than a width of the respective first doped column, a depth of the first trench is smaller than a depth of the respective first doped column, and the first doped regions are adjacent to the respective first doped column.

18. The method of fabricating the semiconductor device as claimed in claim 17, wherein the step for forming the first doped columns comprises:
forming two second trenches in the semiconductor substrate; and
filling the second trenches with an epitaxial material of the second conductive type.

19. The method of fabricating the semiconductor device as claimed in claim 11, after the first doped regions are formed and before the first electrical contact layer is formed, further comprising:
forming a cave on the bottom of the first trench so as to separate the first doped region into two portions; and
forming a third doped region of the second conductive type in the semiconductor substrate at the bottom of the cave.

20. The method of fabricating the semiconductor device as claimed in claim 19, further comprising:
before the thinning step is performed, forming two second doped columns of the second conductive type extending from the opposing surface of the semiconductor substrate toward the first surface with the first trenches being formed in the semiconductor substrate between the two second doped columns; and
after the thinning step is performed, forming fourth doped regions of the first conductive type on the second surface of the semiconductor substrate at the both sides of the first trench respectively and the fourth doped regions connecting to each second doped column respectively.

21. The method of fabricating the semiconductor device as claimed in claim 20, wherein the step of forming the second doped columns comprises:
forming two third trenches in the semiconductor substrate; and
filling the third trenches with the epitaxial material of the second conductive type.

22. The method of fabricating the semiconductor device as claimed in claim 19, wherein the step of forming the cave comprises:
forming a spacer on a sidewall of the first trench to cover a partial surface of the first doped region; and
forming the cave on the bottom of the first trench by using the spacer as a mask.

23. The method of fabricating the semiconductor device as claimed in claim 20, further comprising:
forming a passivation layer on surfaces of the third doped regions before the fourth doped regions are formed; and
removing the passivation layers after the fourth doped regions are formed.

24. The method of fabricating the semiconductor device as claimed in claim 11, further comprising:
filling the first trench with a filling material after the first trenches are formed and before the thinning step is performed; and
removing the filling material after the thinning step is performed and before the first doped regions are formed.
